(19) United States
(12) Patent Application Publication
(10) Pub. No.: US 2012/0228604 A1
(43) Pub. Date: Sep. 13, 2012

(54) THIN FILM TRANSISTOR ARRAY PANEL AND MANUFACTURING METHOD THEREOF

(75) Inventors: Seung-Ha CHOI, Suwon-si (KR); Sung Haeng CHO, Cheongwon-gun (KR); Woo Geun LEE, Yongin-si (KR); Kap Soo YOON, Seoul (KR); Sho Yeon KIM, Yongin-si (KR)

(73) Assignee: SAMSUNG ELECTRONICS CO., LTD., Suwon-si (KR)

(21) Appl. No.: 13/400,931

(22) Filed: Feb. 21, 2012

(30) Foreign Application Priority Data
Mar. 11, 2011 (KR) 10-2011-0021951

(51) Int. Cl. H01L 29/786; H01L 21/336

(52) U.S. Cl. 257/43; 438/104; 257/57; 257/E29.273; 257/E21.411

(57) ABSTRACT

A thin film transistor array panel includes a gate electrode on an insulating substrate, a gate insulating layer on the gate electrode, a semiconductor on the gate insulating layer, a thin film transistor including a source electrode and a drain electrode on the oxide semiconductor, and a pixel electrode which is connected to the drain electrode. The semiconductor includes a first layer having a relatively low fluorine content and a second layer having a relatively high fluorine content. The second layer of the semiconductor is only between the first layer of the semiconductor and the source electrode, and between the first layer of the semiconductor and the drain electrode.

This application claims priority to Korean Patent Application No. 10-2011-0021951 filed on Mar. 11, 2011, and all the benefits accruing therefrom under 35 U.S.C. §119, the entire contents of which are incorporated herein by reference.

### BACKGROUND OF THE INVENTION

(a) Field of the Invention

The invention relates to a thin film transistor (“TFT”) array panel and a manufacturing method thereof.

(b) Description of the Related Art

A liquid crystal display is one of the most widely used flat panel displays, and is a display device that includes two display panels on which electrodes are formed and a liquid crystal layer that is interposed therebetween, and controls the intensity of transmitted light by rearranging the liquid crystal molecules of the liquid crystal layer by applying voltage to the electrodes.

A TFT array panel that is one of two display panels constituting the liquid crystal display is used as a circuit board for independently driving each pixel in a liquid crystal display or an organic electro luminescence (“EL”) display device and the like.

In general, the TFT array panel includes a scanning signal wire or a gate wire that transmits a scanning signal, an image signal line or a data wire that transmits an image signal, a TFT that is connected to the gate wire and the data wire, a pixel electrode that is connected to the TFT, a gate insulating layer that covers and insulates the gate wire, and an interlayer insulating layer that covers and insulates the TFT and the data wire. Like this, forming the TFT array panel including a plurality of thin film layers includes forming a photosensitive film for each thin film layer, and forming a pattern of each layer by etching the thin film layer using the photosensitive film as a mask.

When the TFT array panel including an oxide semiconductor is formed, a characteristic of the semiconductor may be changed during the forming of the TFT array panel.

The above information disclosed in this Background section is only for enhancement of understanding of the background of the invention and therefore it may contain information that does not form the prior art that is already known in this country to a person of ordinary skill in the art.

### BRIEF SUMMARY OF THE INVENTION

The invention has been made in an effort to provide a thin film transistor array panel and a method for manufacturing the same, in which a characteristic of a thin film transistor is not changed depending on a manufacturing process even in the case where an oxide semiconductor is used in the thin film transistor, thereby providing an excellent yield.

An exemplary embodiment of the invention provides a thin film transistor array panel including a gate electrode on an insulating substrate, a gate insulating layer on the gate electrode, a semiconductor on the gate insulating layer, a thin film transistor including a source electrode and a drain electrode on the semiconductor, and a pixel electrode which is connected to the drain electrode. The semiconductor includes a first layer having a relatively low fluorine content and a second layer having a relatively high fluorine content. The first layer of the semiconductor is between the source electrode and the drain electrode.

In an exemplary embodiment, the second layer of the semiconductor may only be between the first layer of the semiconductor and the source electrode, and between the first layer of the semiconductor and the drain electrode.

In an exemplary embodiment, the semiconductor may include an oxide semiconductor.

In an exemplary embodiment, the oxide semiconductor may include indium (In).

In an exemplary embodiment, the source electrode and the drain electrode may each include a first layer and a second layer, and the first layer of the source electrode and the drain electrode may include titanium (Ti), gallium (Ga), zinc (Zn), magnesium (Mg), manganese (Mn), tantalum (Ta), or chromium (Cr).

In an exemplary embodiment, plane shapes of the semiconductor and the source electrode and the drain electrode may be substantially the same to each other with the exception of a channel portion of the thin film transistor.

Another exemplary embodiment of the invention provides a method for manufacturing a thin film transistor array panel, the method including forming a gate electrode on an insulating substrate, layering a gate insulating layer on the gate electrode, forming a semiconductor including a first layer and a second layer on the gate insulating layer, forming a source electrode and a drain electrode on the semiconductor, removing the second layer of the semiconductor between the source electrode and the drain electrode, and forming a pixel electrode connected to the drain electrode.

In an exemplary embodiment, the forming of the semiconductor may include layering an oxide semiconductor on the gate insulating layer, and forming the second layer of the oxide semiconductor and the first layer of the oxide semiconductor by treating a surface of the oxide semiconductor by a fluorine plasma. The first layer of the oxide semiconductor may have a relatively low fluorine content, and the second layer of the oxide semiconductor may have a relatively high fluorine content.

In an exemplary embodiment, the forming of the semiconductor, and the forming of the source electrode and the drain electrode may be simultaneously implemented by using one mask.

In an exemplary embodiment, the removing of the second layer of the semiconductor between the source electrode and the drain electrode may be simultaneously implemented with the forming of the semiconductor and the forming of the source electrode and the drain electrode by using one mask.

According to the exemplary embodiments of the invention, it is possible to strengthen a contact characteristic of a oxide semiconductor with a source electrode and a drain electrode formed after the oxide semiconductor is formed, and to reduce or effectively prevent the oxide semiconductor from unnecessarily reacting with indium in a pixel electrode, by implementing fluorine treatment after the oxide semiconductor layer is layered. It is also possible to reduce or effectively prevent a change in the characteristic of the semiconductor depending on the fluorine treatment of the oxide semiconductor by removing a second layer having a large fluorine amount of a portion used as a channel portion in the oxide semiconductor.

### BRIEF DESCRIPTION OF THE DRAWINGS

The above and other features of this disclosure will become more apparent by describing in further detail exemplary embodiments thereof with reference to the accompanying drawings, in which:

FIG. 1 is a plan view that illustrates an exemplary embodiment of one pixel of a thin film transistor array panel according to the invention.

FIG. 2 is a cross-sectional view that is taken along line II-II of FIG. 1.

FIGS. 3 to 10 are cross-sectional views that sequentially illustrate an exemplary embodiment of a manufacturing method of the thin film transistor array panel shown in FIGS. 1 and 2.

FIG. 11 is a plan view that illustrates another exemplary embodiment of one pixel of a thin film transistor array panel according to the invention.

FIG. 12 is a cross-sectional view that is taken along line XII-XII of FIG. 11.

FIGS. 13 to 21 are cross-sectional views that sequentially illustrate an exemplary embodiment of a manufacturing method of the thin film transistor array panel shown in FIGS. 11 and 12.

### DETAILED DESCRIPTION OF THE INVENTION

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “below,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “lower” relative to other elements or features would then be oriented “above” or “upper” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

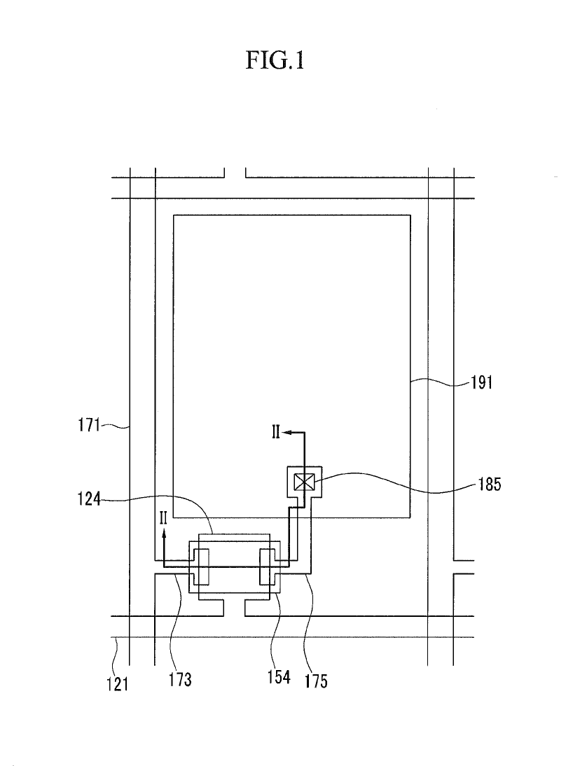

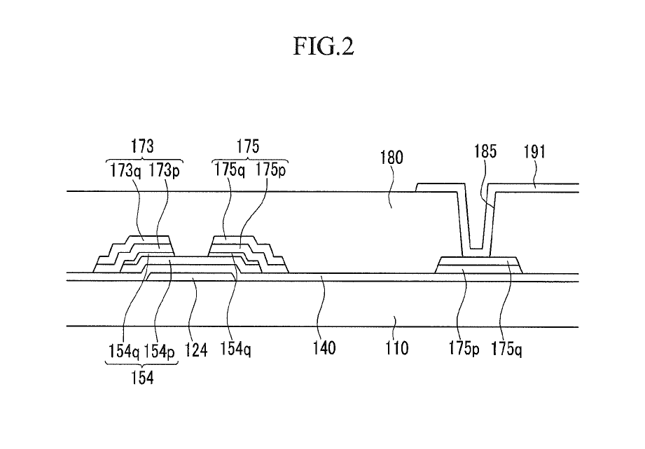

FIG. 1 is a plan view that illustrates an exemplary embodiment of one pixel of a thin film transistor array panel according to the invention, and FIG. 2 is a cross-sectional view that is taken along line II-II of FIG. 1.

Referring to FIG. 1 and FIG. 2, a gate line 121 is on an insulating substrate 110 including a transparent glass or plastic. The thin film transistor array panel may include a plurality of gate lines 121.

The gate line 121 transfers a gate signal and mainly extends in a horizontal (or transverse) direction of the pixel. Each gate line 121 includes a plurality of gate electrodes 124 that protrude from the gate line 121, and an end portion having a wide planar area (not shown) for connection with another layer or external driving circuit.

A gate insulating layer 140 is on the gate line 121, and includes silicon nitride.

An oxide semiconductor 154 is on the gate insulating layer 140. The thin film transistor array panel may include a plurality of oxide semiconductors 154.

The oxide semiconductor 154 includes a first layer 154p and a second layer 154q, and only the first layer 154p of the oxide semiconductor 154 is disposed between a source electrode 173 and a drain electrode 175. The oxide semiconductor 154 may include at least one material selected from zinc (Zn), indium (In), gallium (Ga) or tin (Sn) and oxygen (O). In one exemplary embodiment, for example, the oxide semiconductor 154 may include a mixture oxide such as InZnO, InGaO, InSnO, ZnSnO, GaSnO, GaZnO, and GaInZnO. The oxide semiconductor 154 may be formed by a chemical vapor deposition method, a sputtering method, or a solution process such as inkjet. The second layer 154q of the oxide semiconductor 154 may include a relatively very large amount of fluorine (rich fluoride) as compared to the first layer 154p, and the second layer 154q of the oxide semiconductor 154 may be fluorinated to substitute oxygen with fluorine.

Like this, the generation of an indium protrusion that may occur on the surface of the oxide semiconductor 154 during the manufacturing process may be reduced or effectively prevented by including the second layer 154q, of which a portion of an upper part is fluorinated, of the oxide semiconductor 154. Additionally, a semiconductor characteristic may be increased by increasing a contact characteristic between the first layer 154p of the oxide semiconductor 154 and the source electrode 173, and between the first layer 154p of the oxide semiconductor 154 and the drain electrode 175. Since oxygen in the semiconductor is substituted with fluorine by implementing fluorination treatment in the semiconductor, the generation of a reduced substance of indium oxide by titanium can be controlled.

In addition, since the first layer 154p of the oxide semiconductor 154 having a relatively very low fluorine content is disposed between the source electrode 173 and the drain electrode 175 and is used as a channel of the thin film transistor, a change in the semiconductor characteristic by fluorine may be reduced.

In general, in the case where the fluorine content is high in the oxide semiconductor 154 used as the thin film transistor channel portion, since the fluorine atom may be substituted for the oxygen atom in the oxide semiconductor 154, an oxygen vacancy occurs. Like this, if the oxygen vacancy occurs in the oxide semiconductor 154, since a carrier density is largely increased to increase conductivity so that it is difficult to use the oxide semiconductor 154 as a switching element, the semiconductor may become a conductor. However, in the illustrated exemplary embodiment of the thin film transistor array panel according to the invention, since the first layer 154p of the oxide semiconductor 154 having a relatively very low fluorine content is disposed between the source electrode 173 and the drain electrode 175, it is possible to reduce or effectively prevent conversion of the semiconductor into a conductor according to fluorine.

Like this, in the illustrated exemplary embodiment of the thin film transistor array panel according to the invention, the generation of an indium protrusion that may occur on the surface of the oxide semiconductor 154 during a manufacturing process of the thin film transistor array panel may be reduced or effectively prevented by forming the second layer 154q, of which a portion of an upper part is fluorinated, of the oxide semiconductor 154, and a semiconductor characteristic may be increased by increasing a contact characteristic between the first layer 154p of the oxide semiconductor 154 and the source electrode 173 and the drain electrode 175 formed thereon, respectively. Additionally, since the first layer 154p of the oxide semiconductor 154 having a relatively very low fluorine content is disposed between the source electrode 173 and the drain electrode 175 and is used as a channel of the thin film transistor, in the case of the semiconductor of the channel portion, the oxygen vacancy according to fluorine does not occur, such that a change in the semiconductor characteristic by fluorine may be reduced.

A data line 171 and the drain electrode 175 are on the oxide semiconductor 154 and the gate insulating layer 140. The thin film transistor array panel may include a plurality of data lines 171 and a plurality of drain electrodes 175. The data line 171 transports a data signal and mainly extends in a vertical (or longitudinal) direction of the pixel to cross the gate line 121. Each data line 171 includes a plurality of source electrodes 173 that protrude from the data line 171 and toward the gate electrode 124, and an end portion having a wide planar area (not shown) for connection with another layer or external driving circuit.

The data line 171 including the source electrode 173, and the drain electrode 175 include first layers 173p and 175p and second layers 173q and 175q, respectively. The first layers 173p and 175p of the data line 171 and the drain electrode 175 may include metal such as titanium (Ti), gallium (Ga), zinc (Zn), magnesium (Mg), manganese (Mn), tantalum (Ta), and chromium (Cr) or an alloy thereof. The second layers 173q and 175q of the data line 171 and the drain electrode 175 may include copper (Cu), zinc (Zn), tin (Sn), or aluminum (Al).

The drain electrode 175 is separated from the data line 171 and faces the source electrode 173 with respect to the gate electrode 124. The source electrode 173 and the drain electrode 175 directly contact with the second layer 154q of the oxide semiconductor 154 disposed therebelow.

A passivation layer 180 is on the data line 171, the drain electrode 175 and the exposed first layer 154p of the oxide semiconductor 154. The passivation layer 180 includes an inorganic insulator such as silicon nitride or silicon oxide, an organic insulator, a low dielectric insulator, and the like.

The passivation layer 180 includes a plurality of contact holes 185 which extend completely through a thickness thereof, and expose the drain electrodes 175.

A pixel electrode 191 is on the passivation layer 180. The thin film transistor array panel may include a plurality of pixel electrodes 191. The pixel electrode 191 is physically and electrically connected to the drain electrode 175 through the contact hole 185, and applied with a data voltage from the drain electrode 175. The pixel electrode 191 to which the data voltage is applied determines a direction of liquid crystal molecules of a liquid crystal layer (not shown) between two electrodes by generating an electric field with common electrodes (not shown) of another array panel (not shown) to which common voltage is applied. The pixel electrode 191 and the common electrode form a capacitor (hereinafter, referred to as “a liquid crystal capacitor”) to maintain the applied voltage even after the thin film transistor is turned off.

The pixel electrode 191 may form a sustain storage capacitor by overlapping a sustain electrode line (not shown), and thus, the voltage maintaining ability of the liquid crystal capacitor may be strengthened.

The pixel electrode 191 and contact assistants (not shown) may include a transparent conductor such as indium tin oxide (“ITO”) or indium zinc oxide (“IZO”).

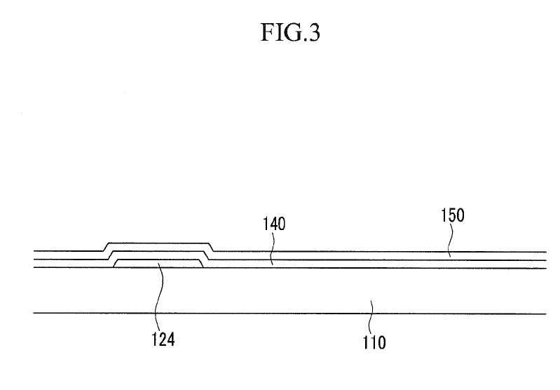

An exemplary embodiment of a method for manufacturing the thin film transistor array panel shown in FIG. 1 and FIG. 2 according to the invention will be described in detail with reference to FIG. 3 to FIG. 10, and FIG. 2. FIGS. 3 to 10 are cross-sectional views that sequentially illustrate an exemplary embodiment of a manufacturing method of the thin film transistor array panel shown in FIG. 1 and FIG. 2, according to the invention.

First, referring to FIG. 3, a metal layer is formed on the insulating substrate 110 which includes transparent glass or plastic and is patterned to form the gate line 121 having the gate electrode 124, the gate insulating layer 140 is layered on the gate electrode 124, and an oxide semiconductor layer 150 is layered thereon in order.

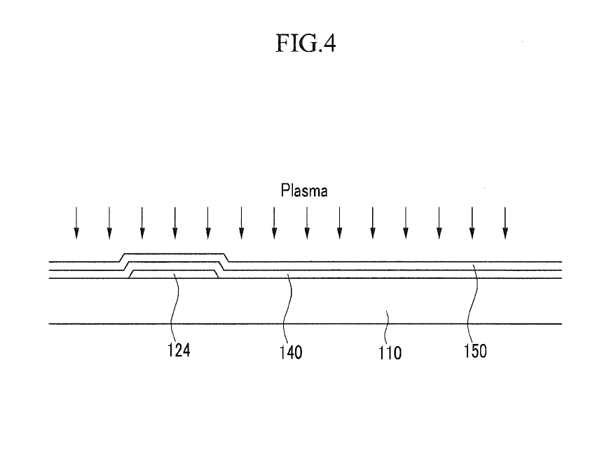

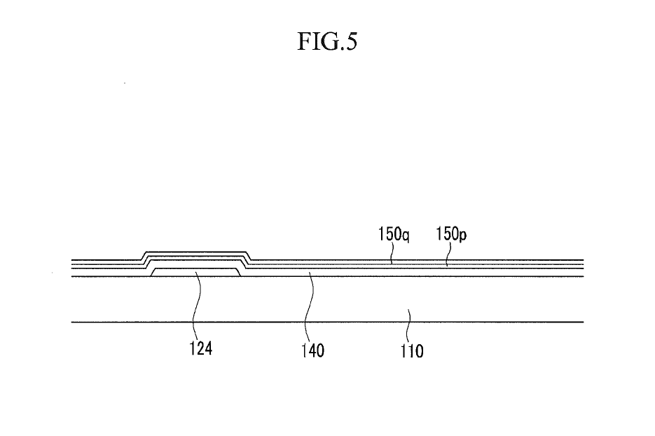

By implementing a fluorine plasma treatment (indicated by the downward arrows) with respect to the oxide semiconductor layer 150 as shown in FIG. 4, a portion of an upper side of the oxide semiconductor layer 150 has a relatively large amount of fluorine, such that the oxide semiconductor layer 150 is converted into the fluorinated second layer 150q in which oxygen is substituted with fluorine, as shown in FIG. 5. The first layer 150p of the oxide semiconductor layer 150 may have a very small amount of fluorine as compared to the second layer 150q.

Like this, the illustrated exemplary embodiment of the method for manufacturing the thin film transistor array panel according to the invention may strengthen a contact characteristic with a source electrode and a drain electrode to be formed later, and reduce or effectively prevent the generation of the indium protrusion that may occur on the surface of the oxide semiconductor during the manufacturing process, by implementing the fluorine plasma treatment after the oxide semiconductor layer 150 is layered.

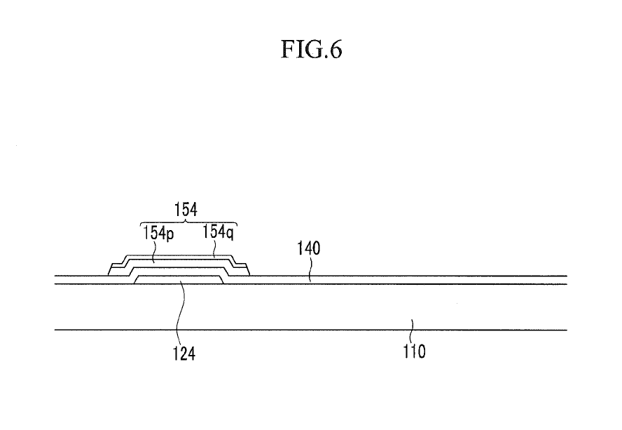

After that, referring to FIG. 6, the first and second layers 154p and 154q of the oxide semiconductor 154 are formed by patterning the oxide semiconductor layer 150, such as by using photolithography.

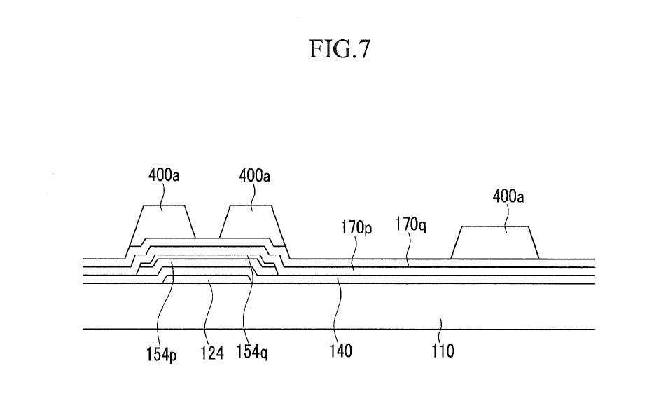

Thereafter, as shown in FIG. 7, a first conductive layer 170p and a second conductive layer 170q are sequentially layered on the first and second layers 154p and 154q of the oxide semiconductor 154, and a first photosensitive film pattern 400a is formed thereon.

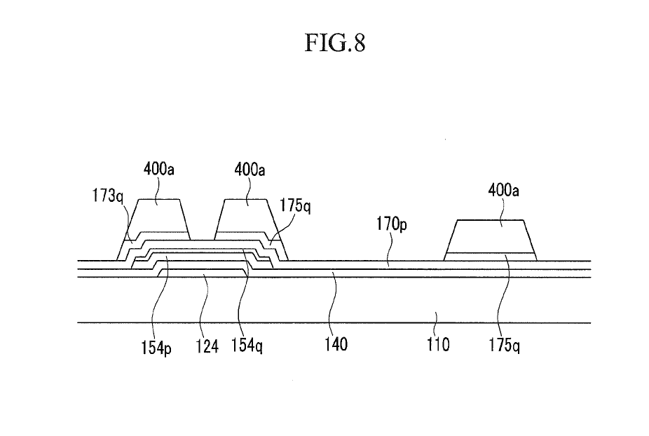

Referring to FIG. 8, the second conductive layer 170q is etched by using the first photosensitive film pattern 400a as an etching mask.

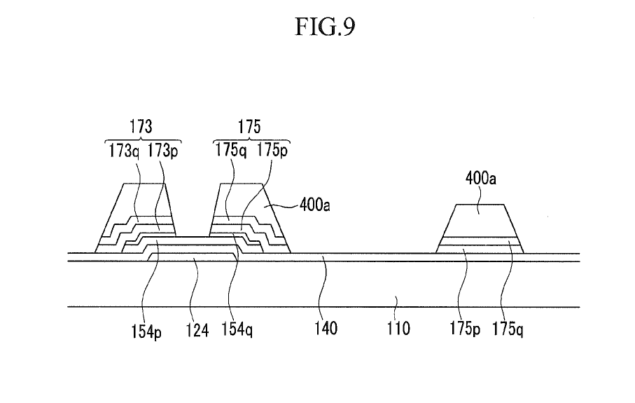

Thereafter, referring to FIG. 9, the data line (not shown), the source electrode 173, the drain electrode 175, and the final oxide semiconductor 154 are accomplished by etching a portion of the first conductive layer 170p and the second layer 154q of the semiconductor 154 using the first photosensitive film pattern 400a as the mask. In this case, all of the second layer 154q of the oxide semiconductor 154 disposed between the source electrode 173 and the drain electrode 175 is removed, such that only the first layer 154p of the oxide semiconductor 154 is disposed between the source electrode 173 and the drain electrode 175.

Like this, the exemplary embodiment of the method for manufacturing the thin film transistor array panel according to the invention may strengthen a contact characteristic between a semiconductor, and a source electrode and a drain electrode formed after the semiconductor is formed, and may reduce or effectively prevent the generation of the indium protrusion that may occur on the surface of the oxide semiconductor during the manufacturing process, by implementing the fluorine treatment after the oxide semiconductor layer is layered. Additionally, the exemplary embodiment of the method for manufacturing the thin film transistor array panel according to the invention may reduce or effectively prevent a change in the semiconductor characteristic according to the fluorine treatment of the oxide semiconductor by removing the second layer having the large amount of fluorine in the oxide semiconductor.

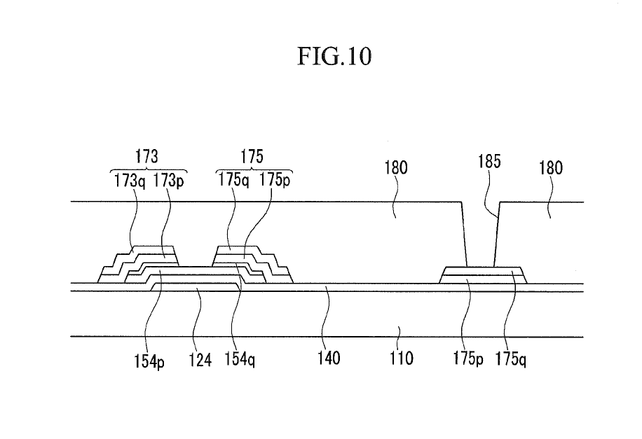

After that, as shown in FIG. 10, the first photosensitive film pattern 400a is removed, the passivation layer 180 is layered, and the contact hole 185 that exposes the drain electrode 175 is formed.

Finally, a metal layer is layered on the passivation layer 180. As shown in FIG. 2, the pixel electrode 191 that is connected to the drain electrode 175 through the contact hole 185 is implemented by layering and patterning the metal layer, such as by using photolithography.

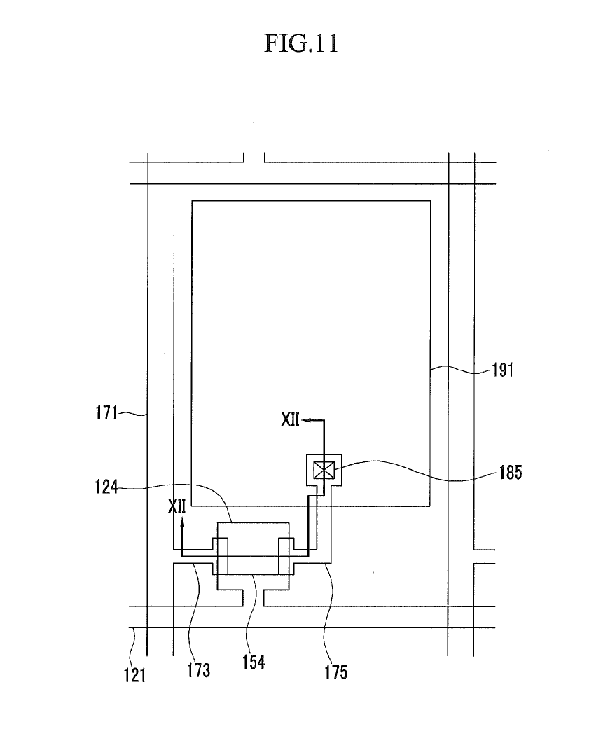

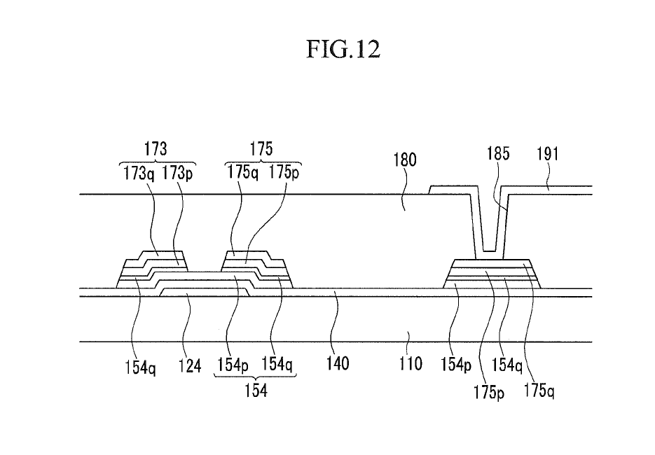

Another exemplary embodiment of a thin film transistor array panel according to the invention will be described with reference to FIG. 11 and FIG. 12. FIG. 11 is a plan view that illustrates another exemplary embodiment of one pixel of a thin film transistor array panel according to the invention, and FIG. 12 is a cross-sectional view that is taken along line XII-XII of FIG. 11.

Referring to FIGS. 11 and 12, the thin film transistor array panel according to the illustrated exemplary embodiment is similar to the thin film transistor array panel according to the exemplary embodiment shown in FIGS. 1 and 2.

Referring to FIG. 11 and FIG. 12, the gate line 121 including a plurality of gate electrodes 124 is on the insulating substrate 110. The thin film transistor array panel may include a plurality of gate lines 121. A gate insulating layer 140 is on the gate line 121, and the oxide semiconductor 154 is on the gate insulating layer 140. The thin film transistor array panel may include a plurality of oxide semiconductors 154. The oxide semiconductor 154 includes a first layer 154p and a second layer 154q, and only the first layer 154p of the oxide semiconductor 154 is disposed between the source electrode 173 and the drain electrode 175, to be described below. The second layer 154q of the oxide semiconductor 154 includes a relatively very large amount of fluorine (rich fluoride) as compared to the first layer 154p, and is formed by fluorination which substitutes oxygen for fluorine.

The gate insulating layer 140, the data line 171 including the plurality of source electrodes 173, and the drain electrode 175 are on the oxide semiconductor 154. The thin film transistor array panel may include a plurality of data lines 171 and a plurality of drain electrodes 175. The data line 171 including the source electrodes 173, and the drain electrode 175 include first layers 173p and 175p and second layers 173q and 175q, respectively. The passivation layer 180 having the contact hole 185 that exposes the drain electrode 175 is on the data line 171, the drain electrode 175, and the exposed first layer 154p of the oxide semiconductor 154. The plurality of pixel electrodes 191 physically and electrically connected to the drain electrode 175 through the contact hole 185 is on the passivation layer 180.

However, in the thin film transistor array panel according to the illustrated exemplary embodiment, unlike the above-mentioned thin film transistor array panel according to the exemplary embodiment shown in FIG. 1 and FIG. 2, a plane shape of the oxide semiconductor 154 is substantially the same as a plane shape of the data line 171, the source electrode 173, and the drain electrode 175. In more detail, the oxide semiconductor 154 has substantially the same plane shape as the data line 171, the source electrode 173, and the drain electrode 175 disposed thereon, with the exception of the first layer 154p of the oxide semiconductor 154 disposed between the source electrode 173 and the drain electrode 175. As illustrated in FIG. 11 and FIG. 12, where the data line 171, the source electrode 173 and the drain electrode 175 overlap the oxide semiconductor 154, the data line 171, the source electrode 173 and the drain electrode 175 are aligned with or contained within boundaries of the oxide semiconductor 154.

All characteristics of the exemplary embodiment of thin film transistor array panel according to the invention described with reference to FIG. 1 and FIG. 2 are applicable to the thin film transistor array panel according to the illustrated exemplary embodiment of the invention.

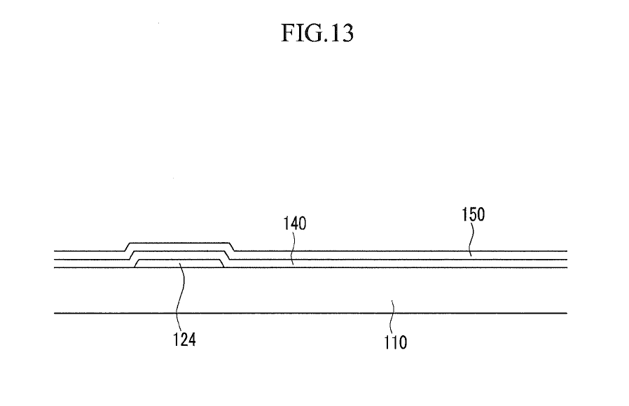

An exemplary embodiment of a method for manufacturing the thin film transistor array panel shown in FIG. 11 and FIG. 12 according to the invention will be described in detail with reference to FIG. 13 to FIG. 21, and FIG. 12. FIG. 13 to FIG. 21 are cross-sectional views that sequentially illustrate an exemplary embodiment of a manufacturing method of the thin film transistor array panel shown in FIG. 11 and FIG. 12, according to the invention.

First, referring to FIG. 13, a metal layer is formed on the insulating substrate 110 which includes transparent glass or plastic and is patterned to form the gate line 121 having the gate electrode 124, the gate insulating layer 140 is layered on the gate electrode 124, and an oxide semiconductor layer 150 is layered thereon in order.

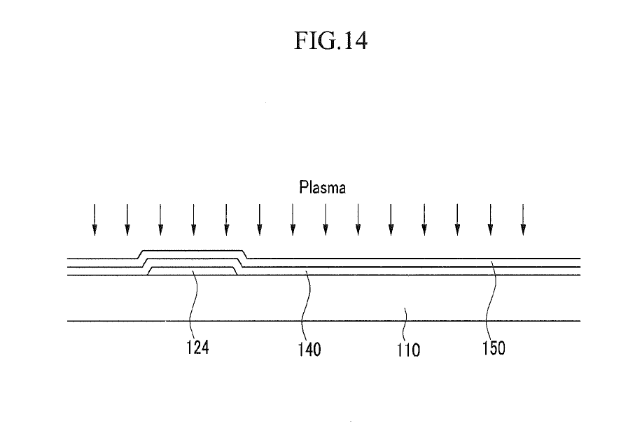

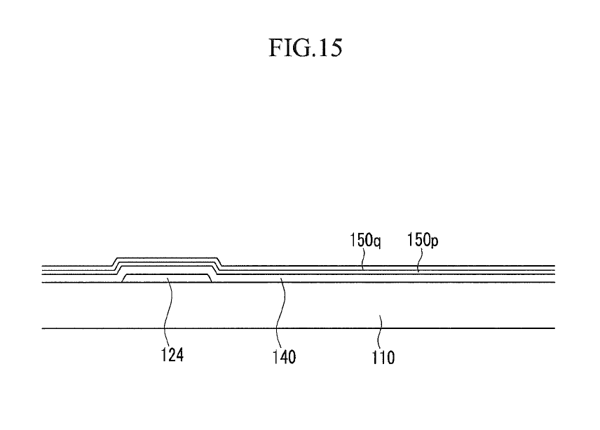

By implementing a fluorine plasma treatment with respect to the oxide semiconductor layer 150 as shown in FIG. 14, a portion of an upper side of the oxide semiconductor layer 150 has a relatively large amount of fluorine, such that the oxide semiconductor layer 150 is converted into the fluorinated second layer 150q in which oxygen is substituted for fluorine, as shown in FIG. 15. The first layer 150p of the oxide semiconductor layer 150 may have a very small amount of fluorine as compared to the second layer 150q.

Like this, the illustrated exemplary embodiment of the method for manufacturing the thin film transistor array panel according to the invention may strengthen a contact characteristic with a source electrode and a drain electrode to be formed later, and reduce or effectively prevent the generation of the indium protrusion that may occur on the surface of the oxide semiconductor during the manufacturing process, by implementing the fluorine plasma treatment after the oxide semiconductor layer 150 is layered.

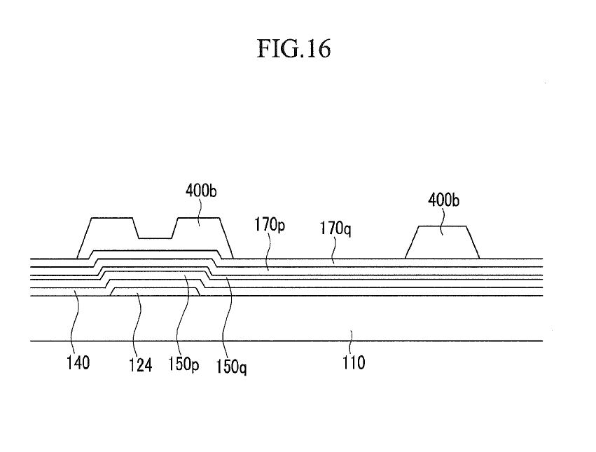

Thereafter, referring to FIG. 16, the first conductive layer 170p and the second conductive layer 170q are layered on the first and second layers 150p and 150q of the oxide semiconductor layer 154, and a second photosensitive film pattern 400b is formed thereon. The second photosensitive film pattern 400b may have different thicknesses according to a position. In detail, a portion corresponding to a position where the data line 171, the source electrode 173, and the drain electrode 175 will be formed becomes a first portion having a first thickness, and a portion corresponding to a position where a channel of the thin film transistor will be formed becomes a second portion having a second thickness.

The ratio of the first thickness of the first portion and the second thickness of the second portion should depend on a process condition in an etching process to be described below, and it is preferable that the second thickness of the second portion is one-half or less of the first thickness of the first portion. As described above, there may be various methods for forming the photosensitive films having different thicknesses according to the position, and as an example thereof, a transparent area, a light blocking area, and a semi-transparent area may be disposed in an exposure mask. In the semi-transparent area, a slit pattern, a lattice pattern or a thin film that has a middle transmittance or a middle thickness is provided. When the slit pattern is used, it is preferable that a width of the slit or an interval between slits is smaller than a resolution of a light exposed that is used in a photolithography process. As another example thereof, a photosensitive film that can reflow may be used. That is, after a photosensitive film pattern that can reflow is formed by using a general mask that has only a transparent region and a light blocking region, the reflow is performed, such that the photosensitive film is allowed to flow down into a region in which the photosensitive film does not remain, thus forming a thin part.

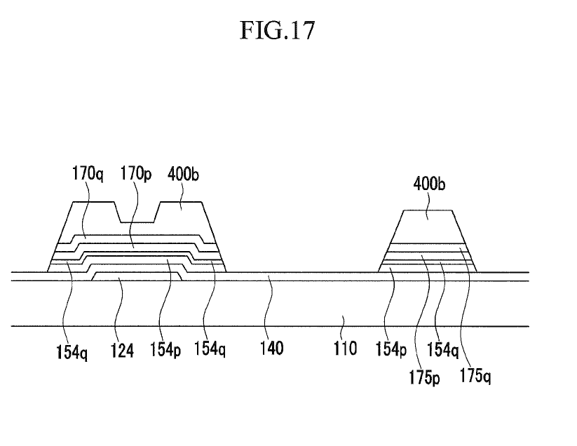

Referring to FIG. 17, the second conductive layer 170q, the first conductive layer 170p, and the first and second layers 150p and 150q of the oxide semiconductor 150 are sequentially etched by using the second photosensitive film pattern 400b as a mask.

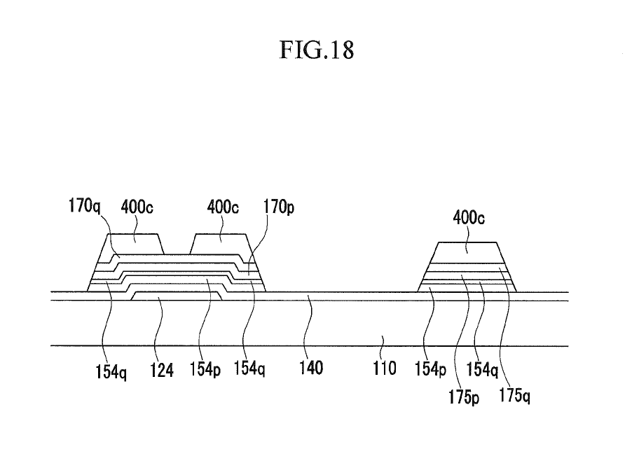

Thereafter, as shown in FIG. 18, all of the photosensitive film pattern disposed in the second portion on which a channel portion will be formed is removed by removing a portion of the second photosensitive film pattern 400b, and a third photosensitive film pattern 400c exposing a position, on which the channel of the thin film transistor will be formed is formed by making a thickness of the photosensitive film pattern disposed in the first portion thin.

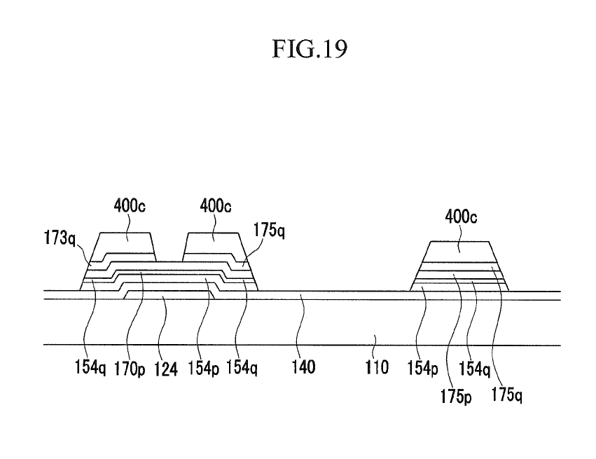

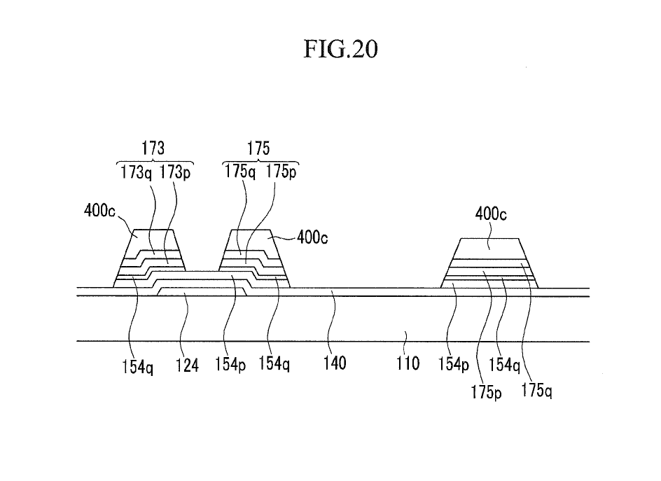

After that, as shown in FIG. 19, the second conductive layer 170q is etched by using the third photosensitive film pattern 400c as the mask. Subsequently, as shown in FIG. 20, a data line (not shown), the source electrode 173, the drain electrode 175, and the oxide semiconductor 154 are accomplished by etching a portion of the first conductive layer 170p and the second layer 154q of the oxide semiconductor 154. In this case, all of the second layer 154q of the oxide semiconductor 154 disposed between the source electrode 173 and the drain electrode 175 are removed, such that only the first layer 154p of the oxide semiconductor 154 is disposed between the source electrode 173 and the drain electrode 175.

Since the method for manufacturing the thin film transistor array panel according to the illustrated embodiment forms the semiconductor 154, the data line 171, the source electrode 173 and the drain electrode 175 by a photolithography process using one mask, it is possible to reduce a manufacturing cost.

In addition, as described above, the exemplary embodiment of the method for manufacturing the thin film transistor array panel according to the invention may strengthen a contact characteristic between a semiconductor and a source electrode and a drain electrode formed after the semiconductor is formed, and may reduce or effectively prevent the generation of the indium protrusion that may occur on the surface of the oxide semiconductor during the manufacturing process, by implementing the fluorine treatment after the oxide semiconductor layer is layered. Additionally, the exemplary embodiment of the method for manufacturing the thin film transistor array panel according to the invention may reduce or effectively prevent a change in the semiconductor characteristic according to the fluorine treatment of the oxide semiconductor by removing the second layer having the large amount of fluorine in the oxide semiconductor.

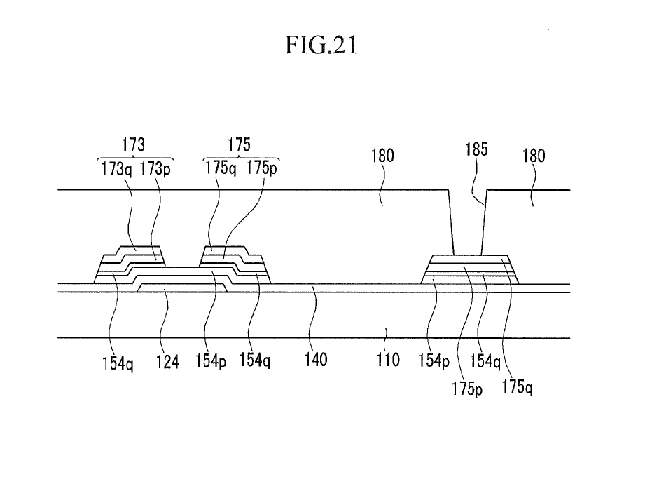

After that, as shown in FIG. 21, the third photosensitive film pattern 400c is removed, the passivation layer 180 is layered, and the contact hole 185 exposing the drain electrode 175 is formed.

Finally, a metal layer is layered on the passivation layer 180. As shown in FIG. 12, the pixel electrode 191 that is connected to the drain electrode 175 through the contact hole 185 is implemented by layering and patterning the metal layer, such as by using photolithography.

All characteristics of the thin film transistor array panel according to the previous exemplary embodiment of the invention described with reference to FIG. 3 to FIG. 10 are applicable to the thin film transistor array panel according to the illustrated exemplary embodiment of the invention.

Performance of an exemplary embodiment of a thin film transistor of a thin film transistor array panel according to the invention will be described. The following is a table that shows performance of the thin film transistor in the case (A) where an upper portion of the oxide semiconductor layer is not fluorinated, in the case (B) where, after the upper portion of the oxide semiconductor layer is fluorinated, the fluorinated oxide semiconductor layer disposed in the channel portion is not removed, and in the case (C) where, like the thin film transistor according to illustrated exemplary embodiment of the invention, after the upper portion of the oxide semiconductor layer is fluorinated, the fluorinated oxide semiconductor layer disposed in the channel portion is removed. The conditions other than the fluorination treatment and the removal of the fluorinated oxide semiconductor layer were the same.

TABLE 1

| | Case | | |
|---|---|---|---|
| | A | B | C |
| Electric charge mobility | 13.06 | 9.95 | 11.83 |
| Threshold voltage at a current | −3.50 | −1.75 | −1.88 |
| of 1 nanoamp (nA) (Vth) | | | |

Referring to Table 1, in the case (A) where the upper portion of the oxide semiconductor layer is not fluorinated, a charge mobility and a threshold voltage are small, but an indium protrusion is generated on the surface of the oxide semiconductor layer. In addition, in the case (B) where, after the upper portion of the oxide semiconductor layer is fluorinated, the fluorinated oxide semiconductor layer disposed in the channel portion is not removed, unlike the case (A), the indium protrusion may not be generated on the surface of the oxide semiconductor, but the charge mobility is largely reduced as compared to the case (A) where the upper portion of the oxide semiconductor layer is not fluorinated. However, with exemplary embodiments of the thin film transistor array panel and the method for manufacturing the same according to the invention, it can be seen that, in the case (C) where, after the upper portion of the oxide semiconductor layer is fluorinated, and the fluorinated oxide semiconductor layer disposed in the channel portion is removed, unlike the case (A), the indium protrusion is not generated on the surface of the oxide semiconductor, the semiconductor characteristic has values within a range similar to that of the case (A), and a characteristic of the thin film transistor is excellent as compared to the case (B).

As described above, in exemplary embodiments of the thin film transistor array panel and the method for manufacturing the same according to the invention, it can be seen that, if after the upper portion of the oxide semiconductor layer is fluorinated, the fluorinated oxide semiconductor layer disposed in the channel portion is removed, the indium protrusion is not formed on the surface of the semiconductor, and the characteristic of the thin film transistor can be excellently maintained.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel, comprising:
a gate electrode on an insulating substrate;
a gate insulating layer on the gate electrode;
a semiconductor on the gate insulating layer and including fluorine;
a source electrode and a drain electrode on the semiconductor; and
a pixel electrode which is connected to the drain electrode,
wherein
the semiconductor includes a first layer having a relatively low fluorine content and a second layer having a relatively high fluorine content, and
the first layer of the semiconductor is between the source electrode and the drain electrode.

2. The thin film transistor array panel of claim 1, wherein:
the second layer of the semiconductor is only between the first layer of the semiconductor and the source electrode, and between the first layer of the semiconductor and the drain electrode.

3. The thin film transistor array panel of claim 1, wherein:
the semiconductor comprises an oxide semiconductor.

4. The thin film transistor array panel of claim 3, wherein:
the oxide semiconductor comprises indium (In).

5. The thin film transistor array panel of claim 4, wherein:
the source electrode and the drain electrode each comprise a first layer and a second layer, and
the first layer of the source electrode and the drain electrode comprises titanium (Ti), gallium (Ga), zinc (Zn), magnesium (Mg), manganese (Mn), tantalum (Ta), or chromium (Cr).

6. The thin film transistor array panel of claim 5, wherein:
plane shapes of the semiconductor, the source electrode, and the drain electrode are substantially similar to each other with the exception of a channel portion of the semiconductor.

7. The thin film transistor array panel of claim 1, wherein:
the source electrode and the drain electrode each comprise a first layer and a second layer, and
the first layer of the source electrode and the drain electrode comprises titanium (Ti), gallium (Ga), zinc (Zn), magnesium (Mg), manganese (Mn), tantalum (Ta), or chromium (Cr).

8. The thin film transistor array panel of claim 7, wherein:
plane shapes of the semiconductor, the source electrode, and the drain electrode are substantially the same to each other with the exception of a channel portion of the thin film transistor.

9. The thin film transistor array panel of claim 1, wherein:
plane shapes of the semiconductor, the source electrode, and the drain electrode are substantially the same to each other with the exception of a channel portion of the thin film transistor.

10. A method for manufacturing a thin film transistor array panel, the method comprising:
forming a gate electrode on an insulating substrate;
layering a gate insulating layer on the gate electrode;
forming a semiconductor including a first layer and a second layer, on the gate insulating layer;
forming a source electrode and a drain electrode on the semiconductor;
removing the second layer of the semiconductor disposed between the source electrode and the drain electrode; and
forming a pixel electrode connected to the drain electrode.

11. The method of claim 10, wherein:
the forming of the semiconductor comprises:
layering an oxide semiconductor on the gate insulating layer, and
forming the second layer of the oxide semiconductor and the first layer of the oxide semiconductor by treating a surface of the oxide semiconductor with a fluorine plasma, and
the first layer of the oxide semiconductor has a relatively low fluorine content, and the second layer of the oxide semiconductor has a relatively high fluorine content.

12. The method of claim 11, wherein:
the oxide semiconductor comprises indium (In).

13. The method of claim 12, wherein:
the forming of the semiconductor, and the forming of the source electrode and the drain electrode are simultaneously implemented by using one mask.

14. The method of claim 13, wherein:
the removing of the second layer of the semiconductor between the source electrode and the drain electrode is simultaneously implemented with the forming of the semiconductor and the forming of the source electrode and the drain electrode by using the one mask.

15. The method of claim 14, wherein:
the source electrode and the drain electrode each comprise a first layer and a second layer, and
the first layer of the source electrode and the drain electrode comprises titanium (Ti), gallium (Ga), zinc (Zn), magnesium (Mg), manganese (Mn), tantalum (Ta), or chromium (Cr).

16. The method of claim 10, wherein:
the semiconductor comprises an oxide semiconductor, and
the oxide semiconductor comprises indium (In).

17. The method of claim 16, wherein:
the forming of the semiconductor, and the forming of the source electrode and the drain electrode are simultaneously implemented by using one mask.

18. The method of claim 17, wherein:
the removing of the second layer of the semiconductor between the source electrode and the drain electrode is simultaneously implemented with the forming of the semiconductor and the forming of the source electrode and the drain electrode by using the one mask.

19. The method of claim 18, wherein:
the source electrode and the drain electrode each comprise a first layer and a second layer, and
the first layer of the source electrode and the drain electrode comprises titanium (Ti), gallium (Ga), zinc (Zn), magnesium (Mg), manganese (Mn), tantalum (Ta), or chromium (Cr).

20. The method of claim 10, wherein:
the forming of the semiconductor, and the forming of the source electrode and the drain electrode are simultaneously implemented by using one mask.

21. The method of claim 20, wherein:
the removing of the second layer of the semiconductor between the source electrode and the drain electrode is simultaneously implemented with the forming of the semiconductor and the forming of the source electrode and the drain electrode by using the one mask.

22. The method of claim 21, wherein:
the source electrode and the drain electrode each comprise a first layer and a second layer, and
the first layer of the source electrode and the drain electrode comprises titanium (Ti), gallium (Ga), zinc (Zn), magnesium (Mg), manganese (Mn), tantalum (Ta), or chromium (Cr).

23. The method of claim 10, wherein:
the source electrode and the drain electrode each comprise a first layer and a second layer, and
the first layer of the source electrode and the drain electrode comprises titanium (Ti), gallium (Ga), zinc (Zn), magnesium (Mg), manganese (Mn), tantalum (Ta), or chromium (Cr).

24. A thin film transistor substrate, comprising:
a gate electrode;
a gate insulating layer which covers the gate electrode;
an oxide semiconductor on the gate insulating layer and including fluorine;
a source electrode which contacts a side of the oxide semiconductor; and
a drain electrode which contacts another side of the oxide semiconductor and is spaced apart from the source electrode,
wherein the oxide semiconductor comprises:
a first region having a relatively low fluorine content and contacting the gate insulating layer, and
a second region having a relatively high fluorine content and contacting the source electrode and drain electrode.
